(19) United States
(12) Patent Application Publication
(10) Pub. No.: US 2026/0215123 A1
(43) Pub. Date: Jul. 23, 2026

(54) VERTICALLY STACKED PIXEL CIRCUIT

(71) Applicant: Avalon Holographics Inc., St. John’s (CA)

(72) Inventors: Arnab Chaudhuri, Ottawa (CA); Greshma Nair, Gloucester (CA); Doug Laing, St. John's (CA)

(21) Appl. No.: 19/368,052

(22) Filed: Oct. 24, 2025

Related U.S. Application Data
(60) Provisional application No. 63/712,113, filed on Oct. 25, 2024.

(51) Int. Cl. H10K 59/00; H10K 59/121

(52) U.S. Cl. CPC H10K 59/751; H10K 59/1213; H10K 59/1216

(57) ABSTRACT

A small scale, vertically stacked pixel circuit having a capacitor, a driving transistor and a switching transistor. The vertically stacked pixel circuit can be used in a backplane for driving high density flat panel LED displays such as active-matrix organic light-emitting diode (AMOLED) backplane displays. A thin film transistor (TFT) design and method of fabrication of a vertically stacked pixel circuit for a vertically stacked TFT array for a high-resolution AMOLED is also described.

### CROSS-REFERENCE TO RELATED APPLICATIONS

This application claims priority to U.S. provisional patent application 63/712,113 filed 25 Oct. 2024, which is hereby incorporated by reference herein in its entirety.

### FIELD OF THE INVENTION

The present invention pertains to a stacked pixel circuit having a capacitor layer and a transistor layer stacked on top of one another. The present invention also pertains to a thin film transistor (TFT) backplane for a high density OLED display.

### BACKGROUND

The flow of current through a field effect transistor (FET) is controlled by an external voltage applied to the gate terminal, which in turn alters the conductivity of the semiconductor material between the drain and source electrodes. FETs, specifically Metal Oxide Semiconductor Field Effect Transistors (MOSFETs) have been developed and improved upon over the last number of years due to their suitability for high current operations. It is argued that many of this century's technological advancements would not have been possible without the MOSFET due to their versatility, specificity, real-time operation capabilities and stability. A thin film transistor (TFT) is a unique type of MOSFET which combines semiconductor films with metal contacts and electrodes with dielectric layers deposited upon a substrate, and can be used in a digital or analogue circuit. A TFT is a three-terminal device having a semiconductor layer, three electrodes (gate electrode, source electrode, and drain electrode), and a gate dielectric layer. The gate electrode is responsible for controlling the current between the source and drain electrodes, which are situated on top of the semiconductor layer. In a TFT, the gate electrode is a layer deposited on a substrate, generally below the semiconductor layer, and the gate electrode and the semiconductor film are separated by a gate dielectric or gate insulator layer. The exposed region of the semiconductor layer between the source and the drain electrodes forms the active area of the TFT device. This active area of the semiconductor, bound by the source and drain electrodes deposited thereon, is also known as a semiconductor channel. Dual gate TFTs have a top gate situated on top of the semiconductor layer separated by a dielectric layer and generally have improved performance compared to single gate TFTs in terms of switching speed and on-off current ratio. The second gate in a dual gate TFTs can provide a number of improvements of device performance including reduction of leakage current, improving frequency response, enhancement of field effect mobility, and improved device stability.

A display, either active or passive matrix, is generally comprised of two planes: a front plane and a backplane. The front plane includes the components that create what a viewer can see, such as LEDs and OLEDs, and the backplane comprises the components that drive the front plane, such as pixel circuits comprising transistors and capacitors. TFTs can be used in active-matrix organic light emitting diode (AMOLED) displays, Liquid Crystal Displays (LCD), Light Emitting Diode (LED) displays, and Organic Light Emitting Diode (OLED) displays to control individual pixels. In AMOLED displays, a TFT array is used to control the voltage applied to each pixel which enables control over the brightness and color resulting in better image quality, higher resolution, and lower power consumption. The capability of TFT devices to switch on and off multiple times per second provides control of pixels in an AMOLED display which appear as if the display content is updating in real-time.

As technology advances, there is a need to miniaturized circuitry for OLED-based displays to produce higher resolution displays with increased pixel density. Ultra-High-resolution displays require smaller pixels with high pixel density, thus requiring that pixel driver circuits in the backplane be smaller in size. To produce a super high-resolution (8000×8000) active-matrix flat panel display, or microdisplay, such as in a light field display, it is desirable that the pixel dimensions be in the range of less than about 10 μm in diameter. To drive a 10×10 μm pixel using a back side driving scheme, for example, a TFT matrix or array in the backplane is required to supply current to each individual colored pixel in the front plane of the display panel in the same dimensions as each pixel. A TFT device is considered a short channel device when the channel length between the source and drain electrodes is of the same order of magnitude as the width of the depletion layer near the source and drain junctions. These short channel devices, or small scale TFTs, often suffer from poorer performance or “short channel effects” due to their short channel length, and can result in high electric fields in the channel region which can lead to increased drain-source leakage currents even when the transistor is supposed to be off. Other short channel effects include, but are not limited to, drain-induced barrier lowering (DIBL), velocity saturation, carrier mobility degradation, impact ionization and hot carrier degradation.

To overcome short channel effects, TFTs can be stacked in different layers which increases the sizes of the individual TFTs. In one example of a microdisplay with reduced pixel size, United States patent U.S. Pat. No. 10,950,178B2 to Wacyk describes a vertically stacked pixel circuit having upper and lower silicon layers electrically connected via a through-silicon via.

This background information is provided for the purpose of making known information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a stacked pixel circuit having a capacitor layer and a transistor layer stacked on top of one another.

In an aspect there is provided a vertically stacked pixel circuit comprising: a substrate; a capacitor layer above the substrate comprising a capacitor having a first capacitor plate, a second capacitor plate, and a dielectric between the first capacitor plate and the second capacitor plate; a transistor layer above the capacitor layer comprising at least one driving transistor and at least one switching transistor, the driving transistor and the switching transistor connected to the first capacitor plate; a data line above the transistor layer connected to the switching transistor; and an organic light emitting diode (OLED) above the data line, the OLED comprising an anode connected to the first capacitor plate.

In an embodiment of the pixel circuit, the driving transistor is connected to the first capacitor plate through a driving transistor gate and the switching transistor is connected to the first capacitor plate through a drain.

In another embodiment of the pixel circuit, the first capacitor plate is closer to the substrate than the second capacitor plate.

In another embodiment of the pixel circuit, one or more the driving transistor and the at least one switching transistor have an extended source electrode.

In another embodiment of the pixel circuit, the anode further comprises a contact metal pad connecting the first capacitor plate to the anode through an anode via, and wherein the anode via and the contact metal pad comprise the same metal.

In another embodiment of the pixel circuit, the driving transistor and the switching transistor are in a single transistor layer.

In another embodiment, the pixel circuit comprises multiple transistor layers, and wherein the driving transistor is in a different transistor layer than the switching transistor.

In another embodiment of the pixel circuit, the data line is between the transistor layer and the anode.

In another embodiment of the pixel circuit, the vertically stacked pixel circuit is part of a thin film transistor backplane for a display device.

In another embodiment of the pixel circuit, each driving transistor and switching transistor comprises a transparent amorphous-oxide semiconductor.

In another embodiment of the pixel circuit, the transparent amorphous-oxide semiconductor comprises amorphous-indium-gallium-zinc-oxide (a-IGZO).

In another embodiment of the pixel circuit, each driving transistor and switching transistor comprise a gate electrode comprising Molybdenum.

In another embodiment of the pixel circuit, each driving transistor and switching transistor comprise gate insulator and etch stop layers comprising Aluminum oxide.

In another embodiment of the pixel circuit, each driving transistor and switching transistor comprise a passivation layer comprising Silicon Dioxide.

In another embodiment of the pixel circuit, each of the driving transistor and the switching transistor is a single gate transistor, dual gate transistor, or an extended source single gate transistor.

In another embodiment of the pixel circuit, the transistor layer comprises more than one switching transistor.

In another embodiment of the pixel circuit, the first capacitor plate and the second capacitor plate are coplanar with the substrate.

In another aspect there is provided a thin film transistor circuit comprising: a substrate; a capacitor layer above the substrate comprising a capacitor comprising a first capacitor plate, a second capacitor plate, and a dielectric between the first capacitor plate and the second capacitor plate; a transistor layer above the capacitor layer comprising at least one driving transistor and at least one switching transistor, the driving transistor and the at least one switching transistor connected to the first capacitor plate; and at least one inter layer dielectric layer between the capacitor layer and the transistor layer.

In an embodiment, the transistor circuit comprises multiple transistor layers, and wherein the driving transistor is in a different transistor layer than the at least one switching transistor.

In another embodiment of the transistor circuit, each of the driving transistor and the at least one switching transistor comprises a transparent amorphous-oxide semiconductor.

Embodiments of the present invention as recited herein may be combined in any combination or permutation.

### BRIEF DESCRIPTION OF THE FIGURES

For a better understanding of the present invention, as well as other aspects and further features thereof, reference is made to the following description which is to be used in conjunction with the accompanying figures which illustrate embodiments or aspects of the invention, where:

FIG. 1 is a schematic of a stacked 2T1C pixel circuit;

FIG. 2 is a cross-sectional view of a 2T1C stacked pixel circuit with a transistor layer having two coplanar single gate transistors;

FIG. 3 is a cross-sectional view of a 2T1C stacked pixel circuit with a transistor layer having non-coplanar transistors;

FIG. 4 is an illustration of a cross-section of a stacked pixel circuit in a pixel device with a transistor layer having coplanar transistors;

FIG. 5 is an illustration of a cross-sectional view of a stacked pixel circuit in a pixel device with first and second transistor layers;

FIG. 6 is a schematic top view of the connections in an example 2T1C stacked pixel circuit with dual gated TFTs;

FIG. 7A illustrates deposition of storage capacitor bottom plate on a display substrate;

FIG. 7B illustrates deposition of an inter layer dielectric and formation of an anode via;

FIG. 7C illustrates deposition of a capacitor top plate and second inter dielectric layer;

FIG. 7D illustrates deposition of third inter dielectric and second via V2;

FIG. 7E illustrates formation of gate electrodes for two TFTs and connection pad V_{DD};

FIG. 7F illustrates deposition of a fourth inter dielectric and semiconductor pads;

FIG. 7G illustrates formation of source and drain for each semiconductor pad;

FIG. 7H illustrates the deposition of a fifth inter dielectric and OLED anode;

FIG. 8 is a cross-sectional view of a 2T1C stacked pixel circuit with a transistor layer having two coplanar dual gate transistors;

FIG. 9 is a cross-sectional view of an example 2T1C stacked pixel circuit with a transistor layer having non-coplanar transistors and extended source electrodes; and

FIG. 10 is a graph of drain voltage vs. drain current of various TFTs.

### DETAILED DESCRIPTION OF THE INVENTION

Unless defined otherwise, all technical and scientific terms used herein have the same meaning as commonly understood by one of ordinary skill in the art to which this invention belongs. Working examples provided herein are considered to be non-limiting and merely for purposes of illustration.

As used in the specification and claims, the singular forms “a”, “an” and “the” include plural references unless the context clearly dictates otherwise.

The term “comprise” and any of its derivatives (e.g. comprises, comprising) as used in this specification is to be taken to be inclusive of features to which it refers, and is not meant to exclude the presence of any additional features unless otherwise stated or implied. The term “comprising” as used herein will also be understood to mean that the list following is non-exhaustive and may or may not include any other additional suitable items, for example one or more further feature(s), component(s) and/or element(s) as appropriate.

As used herein, the terms “having,” “including” and “containing,” and grammatical variations thereof, are inclusive or open-ended and do not exclude additional, unrecited elements and/or method steps, and that that the list following is non-exhaustive and may or may not include any other additional suitable items, for example one or more further feature(s), component(s) and/or element(s) as appropriate. A composition, device, article, system, use, process, or method described herein as comprising certain elements and/or steps may also, in certain embodiments consist essentially of those elements and/or steps, and in other embodiments consist of those elements and/or steps and additional elements and/or steps, whether or not these embodiments are specifically referred to.

As used herein, the term “about” refers to an approximately +/−10% variation from a given value. It is to be understood that such a variation is always included in any given value provided herein, whether or not it is specifically referred to. The recitation of ranges herein is intended to convey both the ranges and individual values falling within the ranges, to the same place value as the numerals used to denote the range, unless otherwise indicated herein.

The use of any examples or exemplary language, e.g. “such as”, “exemplary embodiment”, “illustrative embodiment” and “for example” is intended to illustrate or denote aspects, embodiments, variations, elements or features relating to the invention and not intended to limit the scope of the invention.

As used herein, the terms “connect” and “connected” refer to any direct or indirect physical association between elements or features of the present disclosure. Accordingly, these terms may be understood to denote elements or features that are partly or completely contained within one another, attached, coupled, disposed on, joined together, in communication with, operatively associated with, etc., even if there are other elements or features intervening between the elements or features described as being connected.

As used herein, the term “OLED” refers to an Organic Light Emitting Diode, which is an opto-electronic device which emits light under the application of an external voltage. OLEDs have an emissive electroluminescent layer or organic material or species that emits light in response to an electric current. OLEDs can be divided into two main classes: those made with small organic molecules and those made with organic polymers. Without being bound by theory, when a current is applied to the OLED, the anode injects holes and the cathode injects electrons into the organic layers. The injected holes and electrons each migrate toward the oppositely charged electrode. When an electron and hole localize on the same molecule, an exciton, which is a localized electron-hole pair having an excited energy state, is formed. Light is emitted when the exciton relaxes via a photo emissive mechanism. Types of OLED display technology include but are not limited to Active-matrix OLEDs (AMOLED) and Passive-matrix OLEDs (PMOLED). AMOLEDs have full layers of cathode, organic molecules, and anode. The anode layers have a thin film transistor (TFT) plane in parallel to it so as to form a matrix. This helps in switching each pixel to its on or off state as desired, thus forming an image. Hence, the pixels can be switched off whenever they are not required or there is a black image on the display, decreasing the energy required to illuminate the display. This is the least power consuming type of OLED and has quicker refresh rates which makes them suitable for video. PMOLEDs have a similar composition to AMOLEDs but the cathode lines are arranged at right angles to the anode lines. The electrical control is achieved through the anode and cathode lines to activate the pixel at the intersection point, generating light. The display background of a PMOLED is always black while the color displayed when the pixel is turned on is a predetermined color. PMOLED pixels are fixed to a single color and are not suitable for dynamic imagery or displays. OLEDs may be top or bottom emitting. Top-emitting OLEDs have a substrate that is either opaque or reflective. An OLED is bottom emitting if the emitted light passes through the transparent or semi-transparent bottom electrode and substrate. Top-emitting OLEDs are generally better suited for active-matrix applications as they can be more easily integrated with a non-transparent transistor backplane.

As used herein, the term “electrode” refers to a conductor through which electricity enters or leaves an object, substance, or region.

It is contemplated that any embodiment of the compositions, devices, articles, methods and uses disclosed herein can be implemented by one skilled in the art, as is, or by making such variations or equivalents without departing from the scope of the invention.

Herein is described a small scale, vertically stacked pixel driver circuit. The presently described vertically stacked pixel circuit can be used in a backplane for driving high density flat panel LED displays and microdisplays. A thin film transistor (TFT) design and method of fabrication of a vertically stacked pixel circuit comprising vertically stacked TFTs for a high-resolution active-matrix organic light-emitting diode (AMOLED) backplane is also described. The present TFT devices can be used as high performance small-scale TFT devices in a sub-micron footprint on a TFT array for high-resolution Active-Matrix Organic Light Emitting Diode (AMOLED) displays.

Most pixel driver circuits are coplanar, with transistors and capacitor(s) on the same plane. However, for high density displays, space is limited in the OLED or pixel plane, also referred to as the pixel layer. Generally, in display design, the pixel circuits are on the same plane as the OLED plane with pixel circuits organized on the exterior or perimeter of the display surface and OLEDs arranged on the interior or central region of the display surface. In the present high density display the pixel circuits are organized underneath the OLED plane, which can be referred to as backside driving. This architecture enables a narrow bezel display as the driving circuitry is not arranged at the display edge. This provides a narrow and minimized bezel edge on the display by structuring the pixel circuit in a different plane than the OLED plane. Because the present architecture positions the pixel driver circuits underneath each OLED in the pixel plane in a top emitting device, the present vertically stacked pixel driving circuit can provide all of the required components in a stacked configuration to save space. The present vertically stacked pixel circuit provides a pixel driver design which may be used in a large area, flat panel, high performance, scalable high pixel density display, as well as smaller scale displays such as micro-displays.

With each generation flat-panel display the pixel resolution increases, reducing the pixel size. For example, a 2K reference resolution refers to 2048×1536 pixels. Increasing to a 4K resolution results in a reference resolution of 4096×3072 pixels. With each reduction in pixel size a commensurate reduction must be found for the pixel driving circuit. A high-definition, flat-panel light field display requires a resolution of ~8000×8000 pixels. To achieve the resolution required for a flat-panel light field display, a very high pixel density is highly desirable. The next generation of display technology is the light field display, and even higher pixel resolutions are required to generate a light field. For example, a 4.45 square inch AMOLED light field display panel has a pixel density of ~2500 ppi (pixels per inch). Based on the pixel density requirements for a superior light field display, RGB (red, green, blue) pixel dimensions must be less than 10 μm in size. In the present backside driving architecture, the pixel circuit fits inside the small pixel footprint and is positioned underneath each subpixel in the OLED plane. In traditional AMOLED displays the pixel circuit for each OLED is in the same plane as the OLED plane and positioned on the sides or bezel of the display. In the present instance, for example, for an AMOLED flat-panel display with a 10×10 μm RGB pixel size in the front plane of the display, the active-matrix circuitry dedicated to supplying current to each subpixel (i.e. red subpixel, green subpixel, and blue subpixel) is required, which can be provided as three vertically stacked pixel circuits in that same 10×10 μm footprint, one for each subpixel, in the backplane of the display.

To achieve an active-matrix TFT backplane capable of powering this display, nanoscale TFT devices are required. Downsizing all dimensions of a TFT device can include, for example, reducing the size of each transistor, resulting in shortening the distance between the source and drain electrode, referred to as the channel length, that form the active area of the semiconductor. In the present system, a vertically stacked pixel circuit design is provided that fits at least two transistors and a capacitor in a small footprint.

OLEDs are current driven devices, therefore the requirements for an OLED panel by an active-matrix TFT backplane differ from those for an LCD front plane, for example. OLEDs require constant and consistent current flow to enable light emission. To achieve consistent emission from each pixel, a pixel circuit is used, comprising two or more TFTS and at least one capacitor. As previously described, the pixel size in the front plane of the display dictates the corresponding component dimensions in the backplane. It is this constraint that presents the need for small-scale oxide TFTs. It follows that a high performing miniature TFT device is desired to fit an increased number of these components on a chip, for example.

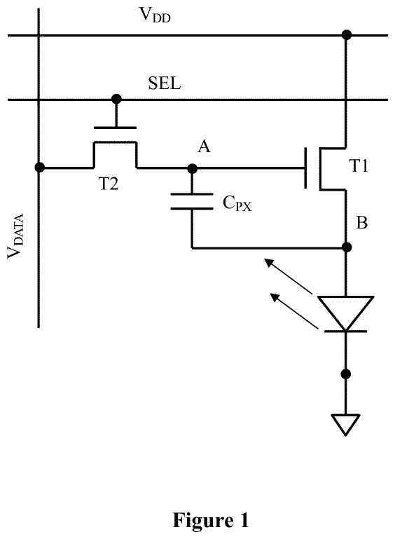

FIG. 1 is a schematic of a 2T1C pixel circuit having one storage capacitor (C_{PX}) and two transistors T1 and T2. This is termed a 2T1C (2 transistors, 1 capacitor) device, and the presently illustrated stacked pixel circuit is one embodiment of a 2T1C device. Driving transistor T1 acts as a voltage controlled current source to supply the necessary current needed for the light emitting devices (OLEDs) in the front plane. In a display panel a drive transistor controls the current flowing to each pixel to produce the desired brightness and color. Switching transistor T2 operates as a switch and can toggle between on and off states to control the flow of current through the circuit. Each of driving transistor T1 and switching transistor T2 are thin film transistors (TFTs) with a metal oxide semiconductor (MOS) structure. Typical single gate TFTs have a three-terminal device with a gate electrode (G), drain electrode (D), and source electrode (S) or source terminal. TFTs can also have a second gate electrode, and these are called dual gate TFTs. Generally, the driving transistor can handle higher current than the switching transistor. Although only one driving transistor and switching transistor is shown, it is understood that a vertically stacked pixel circuit may have, for example, more than one switching transistor and/or more than one driving transistor, and may be utilized for other pixel circuits. The drain of switching transistor T2 is connected to voltage V_{DATA} which is also used to charge the capacitor. When switching transistor T2 is ON, the SEL (select) voltage connected to the gate of switching transistor T2 is high. This takes place during the programming stage. The drain of driving transistor T1 is connected to voltage V_{DD} and the source of driving transistor T1 is connected to the anode of the OLED. The capacitor (C_{PX}) is connected between the gate and source of the T1 and hence the V_{DATA} voltage stored in the capacitor is held across the gate-source of driving transistor T1, which determines the driving current at saturation through the OLED during the emission stage. In some embodiments, a single gated TFT used in the present pixel circuit can have zero parasitic capacitance between the gate-source/drain. Limiting parasitic capacitance in the TFT improves the pixel circuit performance by reducing gray level errors due to faster switching properties of the TFTs. Double gated TFTs can also have zero parasitic gate-source/drain for bottom gate and non-zero parasitic gate-source/drain for the top gate. The combination of the overall lower total parasitic capacitance of gate-source/drain and high transconductance due to double gated architecture can improve the pixel circuit performance by reducing gray level errors due to faster switching properties of the TFTs.

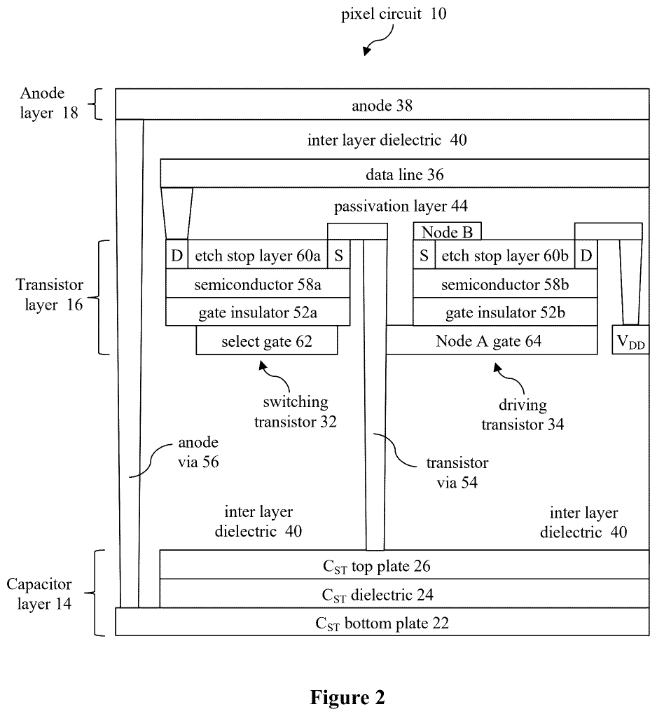

FIG. 2 is a cross-sectional view of a 2T1C stacked pixel circuit 10 with a transistor layer having two coplanar single gate transistors in a single thin film transistor (TFT) layer. Conventional active-matrix organic light emitting diode (AMOLED) pixels have at least two thin film transistors (TFTs), one for switching and one for driving, as well as one storage capacitor. Pixel circuit 10 has a capacitor layer 14, transistor layer 16, and anode layer 18 with anode 38 which can be connected to an OLED, and is supported by a substrate (not shown) under capacitor layer 14. Examples of substrates include glass and silicon. Capacitor layer 14 has a storage capacitor with a capacitor (C_{ST}) bottom plate 22, capacitor (C_{ST}) top plate 26, and capacitor (C_{ST}) dielectric 24 therebetween. In this embodiment, transistor via 54 connects the capacitor top plate 26 to switching transistor 32 and driving transistor 34, and anode via 56 connects capacitor bottom plate 22 to anode 38 in an OLED of a pixel. In other embodiments a transistor via can connect the transistors to the bottom plate of the capacitor and an anode via can connect the anode to a top plate of the capacitor. V_{DD} is a power supply which connects to the drain electrode (D) of driving transistor 34.

The terms “capacitor” and “storage capacitor” are used interchangeably herein. The capacitor plates can be made from any suitable material including but not limited to one or more of Indium Tin Oxide (ITO), Aluminum (Al), Copper (Cu), Gold (Au), Silver (Ag), Tin (Sn), Nickel (Ni), Zinc (Zn), Titanium (Ti), Platinum (Pt), Molybdenum (Mo), Tungsten (W), and Tantalum (Ta). Data line 36 between the transistor layer 16 and anode layer 18 connects to switching transistor 32 to toggle the pixel circuit on or off as desired. An inter layer dielectric 40 between the electrical components of the pixel circuit serves to isolate the electrical components of the circuit and maintain the electrical integrity of the circuit. Examples of materials that may be used for the inter layer dielectric 40 include but are not limited to silicon dioxide (SiO₂), polymeric dielectric layers such as spin-on benzocyclobutene (BCB), teflon, vapor deposited parylene, and fluorinated organic polymers, as well as other low dielectric constant materials. Passivation layer 44 between the transistor layer 16 and data line 36 serves as a protective layer and prevents chemical interactions that could degrade the performance of the transistors and other elements in the circuit. Examples of materials that may be used for the passivation layer include but are not limited to silicon nitride (Si₃N₄) and silicon dioxide (SiO₂).

The semiconductor layer may comprise one or more of an oxide of at least one of, for example, Indium (In), Germanium (Ge), Chromium (Cr), Zirconium (Zr), Gallium (Ga), Tin (Sn), Cadmium (Cd), Vanadium (V), Hafnium (Hf), Cesium (Cs), Cerium (Ce), Titanium (Ti), Aluminum (Al), and Zinc (Zn). In some embodiments, the semiconductor layers comprise a Zn-oxide-based material such as one or more of a Zn-oxide, In—Zn oxide, and Ga—In—Zn oxide. In some embodiments, the semiconductor layers comprises In—Ga—Zn-O (IGZO), c-axis aligned crystalline Indium Gallium Zinc Oxide (CAAC-IGZO), In—Sn—Zn—O (ITZO), tungsten-doped indium zinc oxide (IWZO), or In—Ga—Sn—Zn—O (IGTZO), or a metal-oxide mixture metal oxides of Zinc (Zn), Indium (In), Gallium (Ga), and Tin (Sn). The semiconductor layers generally comprise a channel, a drain, and a source, the drain and the source being on opposite sides of the channel. The semiconductor layers can comprise a single layer or a multi-layer of semiconductor material. Preferably the semiconductor layer comprises indium-gallium-zinc-oxide (IGZO), and more preferably the semiconductor layer comprises amorphous-indium-gallium-zinc-oxide (a-IGZO). Amorphous IGZO (a-IGZO) has lower off current and uniformity than low-temperature polycrystalline silicon (LTPS) and other amorphous silicon technologies which are presently used for high density small pixels. One advantage of using a-IGZO is that the off current is lower than the current needed for the desired brightness of the small OLEDs. a-IGZO is also significantly cheaper than LTPS and can be formed using a less complex process than what is needed for LTPS. Indium gallium zinc oxide (IGZO) has shown to be less prone to the adverse effects of DIBL, providing better performance in a short channel architecture. In oxides, such as IGZO, oxygen vacancies and hydrogen atoms are the carrier-generation sources (i.e., donors). In one example, simultaneous introduction of oxygen vacancies and hydrogen impurities has been shown to result in increased carrier concentration.

Each of the transistors 32, 34 in the transistor layer has, in series, a gate electrode, select gate 62 and Node A gate 64, respectively, gate insulator 52a, 52b, semiconductor 58a, 58b, and an etch stop layer 60a, 60b. In each transistor, current flows from a source terminal(S) through the semiconductor layer, to the drain terminal (D). In the transistors shown, the gate electrode for the switching transistor 32 is a select gate 62, and the gate electrode for the driving transistor 34 is Node A gate 64 which is connected to the capacitor top plate 26. In some embodiments, the gate electrode comprises Molybdenum (Mo), Gold (Au), Aluminum (Al), Silver (Ag), Titanium (Ti), or a combination thereof.

The gate insulator 52a, 52b in each transistor serves to isolate the layers and provide gate field effect. In some embodiments the gate dielectric layer comprises a single layer of SiO₂, a single layer of Al₂O₃, HfO₂, SiNₓ, or a SiO₂ and Al₂O₃ bilayer. The etch stop layer 60a, 60b protects the active semiconductor region from exposure to etchants needed for etching source and drain and can be made from the same materials as the gate insulator. It is noted that the capacitor in the present architecture is in a different layer than the TFTs, which provides vertical stacking of the functional circuit components. This vertical stacking enables a planar capacitor orientation where the capacitor plates are coplanar with the substrate and transistor layer. A trench capacitor may also be used in the capacitor layer. Planar capacitors provide a simpler fabrication process as each component in the capacitor can be layered sequentially, whereas a trench capacitor may require more intricate etching and filling processes.

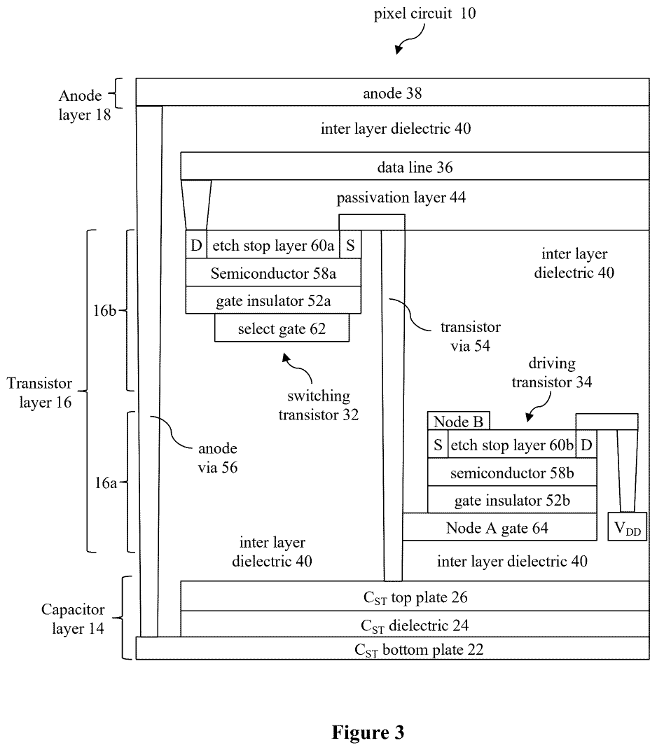

FIG. 3 is a cross-sectional view of a 2T1C stacked pixel circuit 10 with a transistor layer having non-coplanar transistors in the transistor layer. The shown 2T1C stacked pixel circuit 10 is supported by a substrate (not shown) and the transistor layer 16 has first transistor layer 16a and second transistor layer 16b. Capacitor layer 14 has a storage capacitor with a capacitor (C_{ST}) bottom plate 22, capacitor (C_{ST}) top plate 26, and capacitor (C_{ST}) dielectric layer 24 therebetween. Above the capacitor layer 14 and insulated with a inter layer dielectric (ILD) 40 is a transistor layer 16 having a switching transistor 32 and driving transistor 34. Data line 36, insulated and/or protected by inter layer dielectric 40 and passivation layer 44, is connected to the drain (D) of switching transistor 32 to switch the switching transistor 32 ON and OFF as desired. Other inter layer dielectric 40 layers in pixel circuit 10 between electrical components provide insulating properties to isolate current flow in the circuit. In the pixel circuit shown there is one of each of a switching transistor 32 and driving transistor 34, however it is understood that other pixel circuit arrangements may have one or more of each of a switching transistor and driving transistor. Anode layer 18 with anode 38 is part of and supplies power to an OLED pixel above the pixel circuit 10. Each of the switching transistor 32 and driving transistor 34 in the transistor layer has, in series, a gate electrode layer, gate insulator 52a, 52b layer, semiconductor 58a, 58b layer, and an etch stop layer 60a, 60b. In each transistor, current flows from a source terminal (S) through the semiconductor layer, to the drain terminal (D). In the transistors shown, the gate electrode for the switching transistor 32 is a select gate 62, and the gate electrode for the driving transistor 34 is a Node A gate 64 which is connected to the capacitor top plate 26. The gate insulator in each transistor serves to insulate the semiconductor layer from the gate electrode. Transistor via 54 connects one of the plates of the storage capacitor to the gate electrode of the driving transistor 34 and the source electrode(S) of the switching transistor 32, and anode via 56 connects the other plate of the storage capacitor to the anode 38 in the anode layer 18. V_{DD} is a power supply which connects to the drain electrode (D) of driving transistor 34. In the embodiment shown in FIG. 3, the driving transistor 34 is in a first transistor layer and the switching transistor 32 is in a second transistor layer, however it is also possible to have the switching transistor 32 in a lower transistor layer and the driving transistor 34 in a higher transistor layer. In both cases inter layer dielectric 40 shields and isolates the transistors in the transistor layer 16.

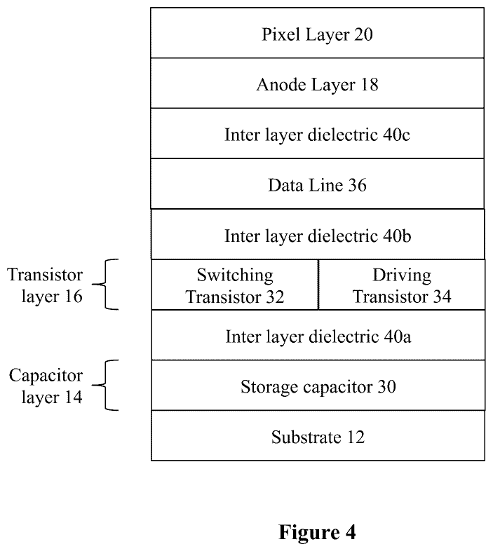

FIG. 4 is an illustration of a cross-section of a stacked pixel circuit in an emissive pixel device with a transistor layer having non-coplanar transistors. The pixel circuit is assembled on a substrate 12 which supports the back plane of a pixel layer 20 having an array of pixels. The pixel array can be part of, for example, an AMOLED or light field display device, and have a plurality of individually controllable pixels. Above the substrate 12 in the vertically stacked pixel circuit is a storage capacitor 30 in a capacitor layer 14, followed by a first inter layer dielectric 40a. Insulated from the capacitor is a transistor layer 16 with a switching transistor 32 and a driving transistor 34 in a single transistor layer 16. Above the transistor layer 16 is a second inter layer dielectric 40b followed by a data line 36, above which is a third inter layer dielectric 40c. Above that, anode layer 18 followed by pixel layer 20 provides the pixel circuit backplane and front plane in an emissive pixel device.

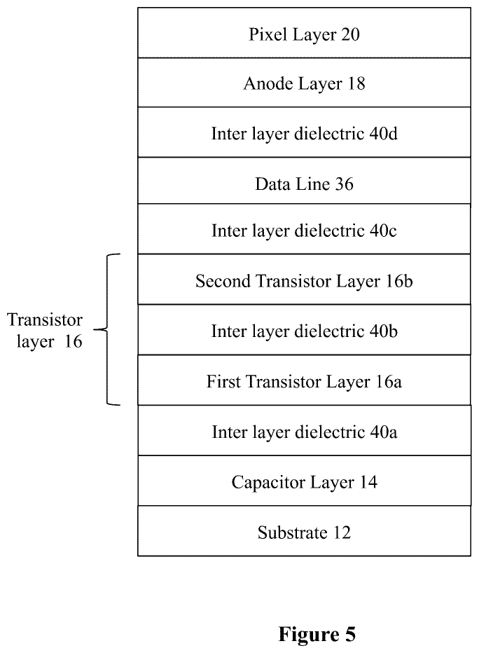

FIG. 5 is an illustration of a cross-sectional view of a stacked pixel circuit in a pixel device with first and second transistor layers. The pixel circuit is assembled on a substrate 12 which supports the backplane of a pixel layer 20 having an array of pixels. The pixel array can be part of, for example, an AMOLED or light field display device, and have a plurality of individually controllable pixels. Above the substrate 12 in the vertically stacked pixel circuit is a capacitor layer 14 with storage capacitor, followed by a first inter layer dielectric 40a. Insulated from the capacitor layer 14 is a transistor layer 16 having a first transistor layer 16a and a second transistor layer 16b separated by a second inter layer dielectric 40b. The switching transistor(s) and driving transistor are each in a different transistor layer, but each may be either in the first transistor layer 16a or second transistor layer 16b. Above the transistor layers is a third inter layer dielectric 40c followed by a data line 36, above which is a fourth inter layer dielectric 40d. Above that, anode layer 18 followed by pixel layer 20 provides the pixel circuit TFT backplane and front plane in an emissive pixel device.

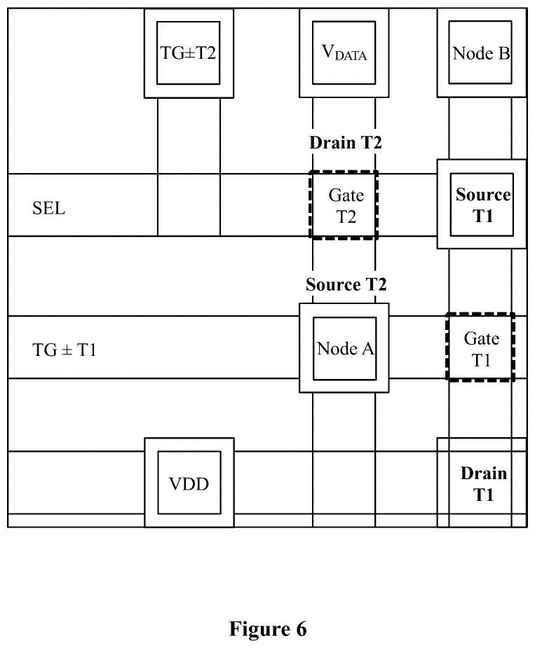

FIG. 6 is a schematic top view of the connections in an example 2T1C stacked pixel circuit with dual gated TFTs. Node A is connected to the gate electrode of drive transistor T1 and the source electrode of switching transistor T2. Node B is connected to the source of driving transistor T1 and bottom place of the capacitor and the anode of the OLED. Select line (SEL) is the gate terminal for select/switching transistor T2. For charge to be induced between the source and drain electrodes in a TFT, a low V_{DS} value (V_{DS}<V_{GS}−Vₜₕ) is required to form a charge distribution gradient between the source and drain electrodes. A charge distribution gradient results when a group of individually charged particles at the source electrode is separated from a region without a charge, i.e. the drain electrode. To induce current in the channel, the gate voltage, V_{GS} must be greater than the threshold voltage, Vₜₕ. The threshold voltage, Vₜₕ, is the minimum gate to source voltage, V_{GS}, needed to create the conducting path along the semiconductor channel between the source and drain electrodes in a TFT. In other words, for V_{GS}<Vₜₕ, the device is considered OFF and for V_{GS}>Vₜₕ, the device is turned ON. The voltages of the terminals of the select in the switching transistor and node A and B in the driving TFTs depend on the driving scheme and the number of sub-stages of programming. In one example, the select in the switching TFT can be either ON or OFF, and this is achieved by having the gate of the switching TFT switch between a high positive voltage, for example about 5V-10V and a high negative voltage, for example about −5V to −10V). Assuming the threshold voltage of the TFT is close to 0 V, which is true for IGZO TFTs, even if the threshold voltage is slightly positive, for example about 1.5 V, or slightly negative, for example −1.5 V, the example gate voltages will work to drive the circuit. It is preferred that the driving TFT has a drain voltage V_{DD} usually at a high positive value, for example about 10 to 15 V. The V_{DATA} voltage range will depend on the OLED size, OLED efficiency, and the luminance requirements of the particular application.

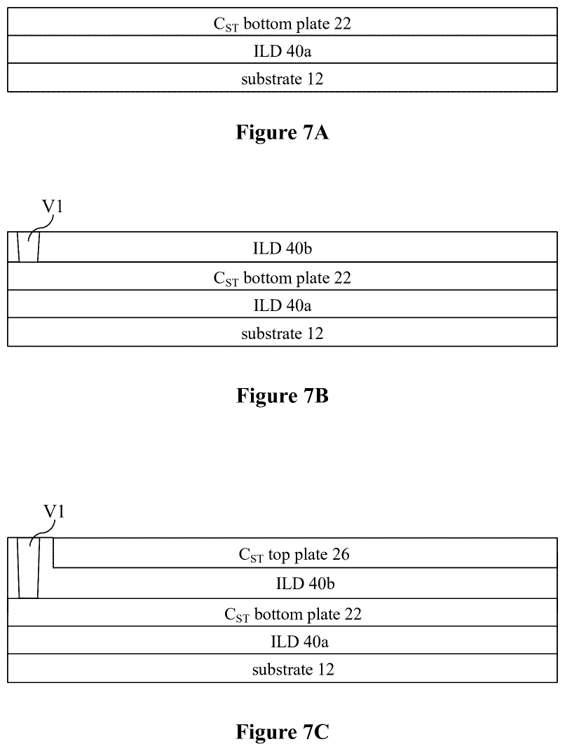

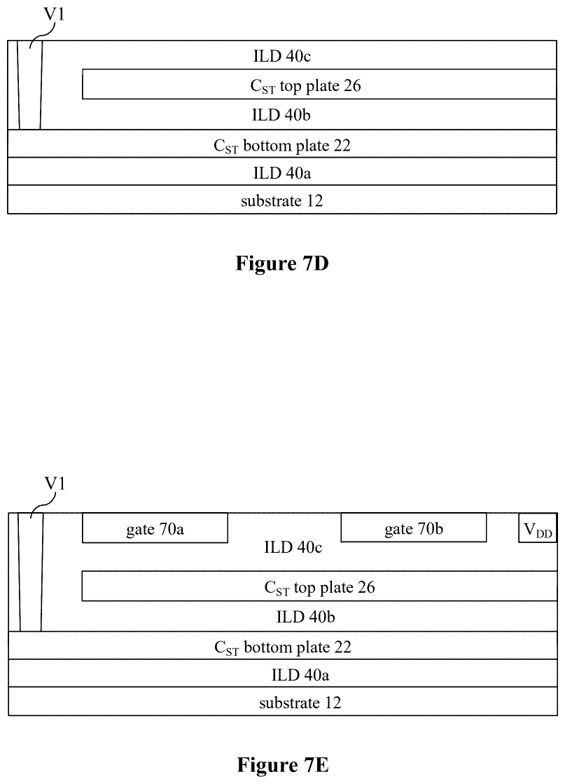

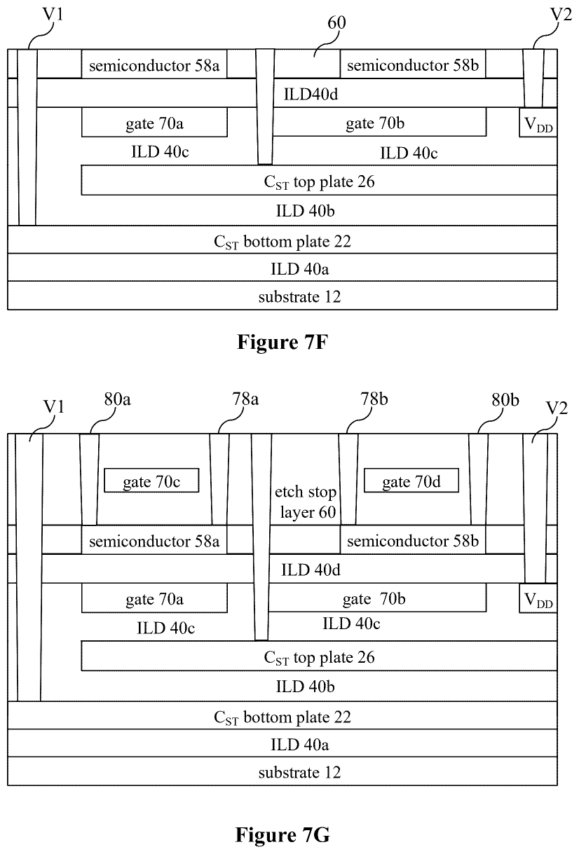

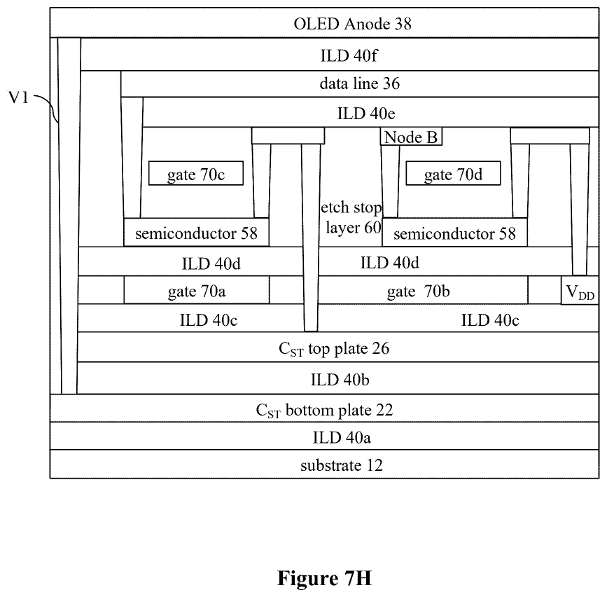

FIGS. 7A-7H comprise processing steps for manufacturing a vertically stacked thin film transistor. In FIG. 7A a storage capacitor bottom plate C_{ST} 22 is deposited on an underlying first inter layer dielectric ILD 40a which is on top of a display substrate 12. In FIG. 7B, second inter layer dielectric ILD 40b is deposited and ILD 40b is patterned and etched for a first via V1. In FIG. 7C the capacitor top plate 26 of C_{ST} is deposited with metal deposition to fill via V1 and second inter dielectric ILD 40b. Patterning and etching of the top plate and the corresponding contact pad is then done to remove unwanted metals. In FIG. 7D third inter dielectric ILD 40c is deposited with patterning and etching for deposition of metal on first via V1. FIG. 7E illustrates deposition and etching of gate electrodes 70a and 70b for driving transistor and select/switching transistor TFTs, and connection pad V_{DD}. FIG. 7F illustrates deposition of fourth inter dielectric ILD 40d followed by semiconductor 58a, 58b pads for driving transistor and select/switching transistor TFTs, respectively, together with second via V2. The semiconductor pads are aligned, patterned, and etched into islands, followed by coating with etch stop layer 60. FIG. 7G illustrates the etching and deposition of source and drain metals for the source 78a, 78b and drain 80a, 80b for each semiconductor pad 58a, 58b, respectively, as well as top gates 70c, 70d for dual gated TFTs. FIG. 7H illustrates the deposition of fifth inter dielectric ILD 40e followed by patterning and etching of ILD 40e for via V1 and data line 36. Depositioning and patterning of the V_{DATA} metal line and the corresponding contact pad for connection to the drain of select TFT is also done in this step, followed by deposition of sixth inter dielectric ILD 40f. Metal deposition followed by patterning and etching planarizes the top surface and extends via V1 for contact with subsequently deposited OLED anode 38.

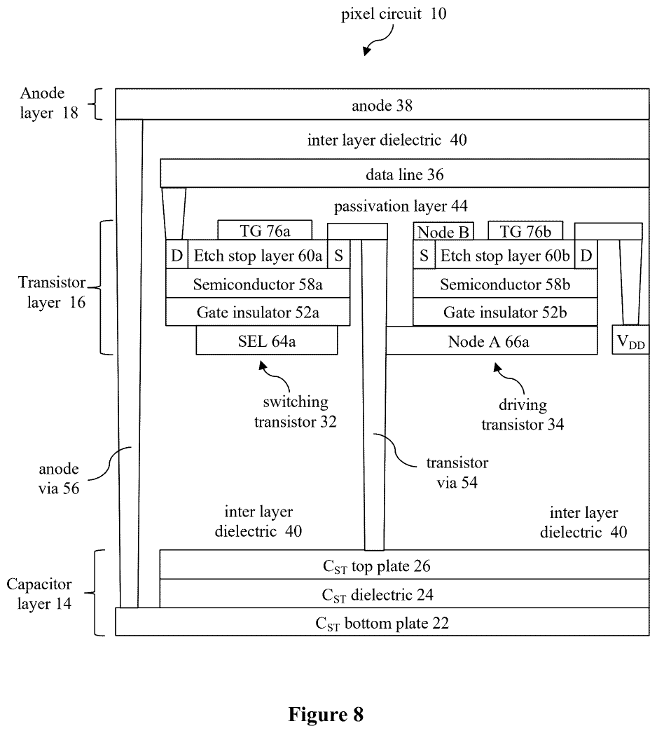

FIG. 8 is a cross-sectional view of a 2T1C stacked pixel circuit with a transistor layer having two coplanar dual gate transistors. Although dual gate TFTs require additional manufacturing steps, they have some advantages compared to single gate TFTs. One advantage of a dual gate structure is that dual gate TFTs can provide a higher gate field effect, which allows for better control over the TFT properties. A higher gate field effect provides higher field effect mobility, higher currents, lower DIBL, better saturation, and lower sub-threshold swing. These can result in faster switching speeds and lower off currents and therefore improved performance in driving pixels in displays, leading to brighter images and better overall visual quality. Dual gate TFT pixel circuit 10 shown has a capacitor layer 14, transistor layer 16, and anode layer 18 with anode 38 which can be connected to an OLED, and is supported by a substrate (not shown) under capacitor layer 14. Capacitor layer 14 has a storage capacitor with a capacitor bottom plate 22, capacitor top plate 26, and capacitor dielectric 24 therebetween. In this embodiment, transistor via 54 connects the capacitor top plate 26 to switching transistor 32 and driving transistor 34, and anode via 56 connects capacitor bottom plate 22 to anode 38 in an OLED of a pixel. In other embodiments a transistor via can connect the transistors to the bottom plate of the capacitor and an anode via can connect the anode to a top plate of the capacitor. V_{DD} is a power supply which connects to the drain electrode (D) of driving transistor 34. Data line 36 between the transistor layer 16 and anode layer 18 connects to switching transistor 32 to toggle the pixel circuit on or off as desired. An inter layer dielectric 40 between the electrical components of the pixel circuit serves to isolate the electrical components of the circuit and maintain the electrical integrity of the circuit. Passivation layer 44 between the transistor layer 16 and data line 36 serves as a protective layer and prevents chemical interactions that could degrade the performance of the transistors and other elements in the circuit. Each of the transistors in the transistor layer has, in series, a gate electrode, gate insulator 52a, 52b, semiconductor 58a, 58b, an etch stop layer 60a, 60b, and a top gate forming the dual gate architecture. In each transistor, current flows from a source terminal(S) through the semiconductor layer, to the drain terminal (D). In the transistors shown, the bottom gate electrode for the switching transistor 32 is select gate (SEL) 64a and the top gate is top gate TG 76a. The gate electrodes for the driving transistor 34 are bottom gate Node A 66a and top gate TG 76b.

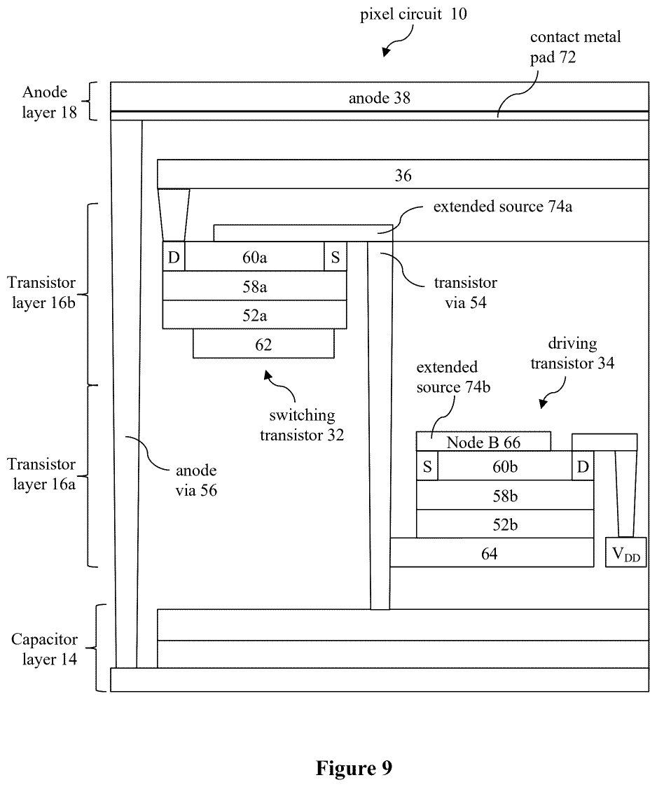

FIG. 9 is a cross-sectional view of an example 2T1C stacked pixel circuit 10 with a transistor layer 16 having non-coplanar transistors and extended source electrodes. Transistor layers 16a, 16b positioned above capacitor layer 14, which is supported by a substrate. Switching transistor 32 comprises select gate 62, gate insulator 52a, semiconductor 58a, and etch stop layer 60a, and driving transistor 34 comprises Node A gate 64, gate insulator 52b, semiconductor 58b, and etch stop layer 60b. In the embodiment as shown, source electrodes connected to each of switching transistor 32 and driving transistor 34 are extended over the TFT semiconductor layer of each transistor. In switching transistor 32 extended source 74 a is connected to transistor via 54 and extends over the semiconductor 58a, and in driving transistor 34, extended source 74b is connected to Node B gate 66 and extends over the semiconductor 58b. The presence of an extended source electrode can improve saturation performance for a single gated TFT. This helps reduce the grey level error (also known as emission current error), which is the error between the target drive current and the actual drive current, for pixel circuits. The presence of an extended source can also prevent light transmission through to the TFTs from the OLED light emission structures above. Data line 36 is connected to the drain of switching transistor 32. Also shown is an optional metal layer, also referred to as contact metal pad 72 which is positioned between anode via 56 and anode 38 in anode layer 18. Contact metal pad 72 is preferable of the same metal as anode via 56 and acts to reduce contact resistance between the via and the anode. The cross section of anode via 56 is small compared to the anode, so by adding an additional metal layer, contact metal pad 72, made of a similar or the same material as anode via 56, reduces the contact resistance between the via 56 to anode 38 by increasing the effective area of the contact between the two. Increasing the contact surface area between the source electrode of a thin-film transistor (TFT) and the anode of an organic light-emitting diode (OLED) reduces contact resistance by enhancing several key aspects of electrical conduction. With a larger contact area, more conduction pathways are available for the flow of charge carriers, which lowers the current density and spreads the electrical load more evenly. This allows for more efficient injection of charge carriers from the TFT into the OLED, improving overall charge transfer. Additionally, larger contact areas reduce the occurrence of current crowding, where high current density at specific points can increase localized resistance. The increased surface area also helps minimize the impact of interface defects, such as resistive spots or poor adhesion, as these imperfections become less significant relative to the total contact area. By reducing these sources of resistance, the system achieves better charge transfer and lower energy loss, resulting in improved performance. Further, this reduced contact resistance can lower the resistive-capacitive (RC) delay of the overall circuit and this results in lower grey level error.

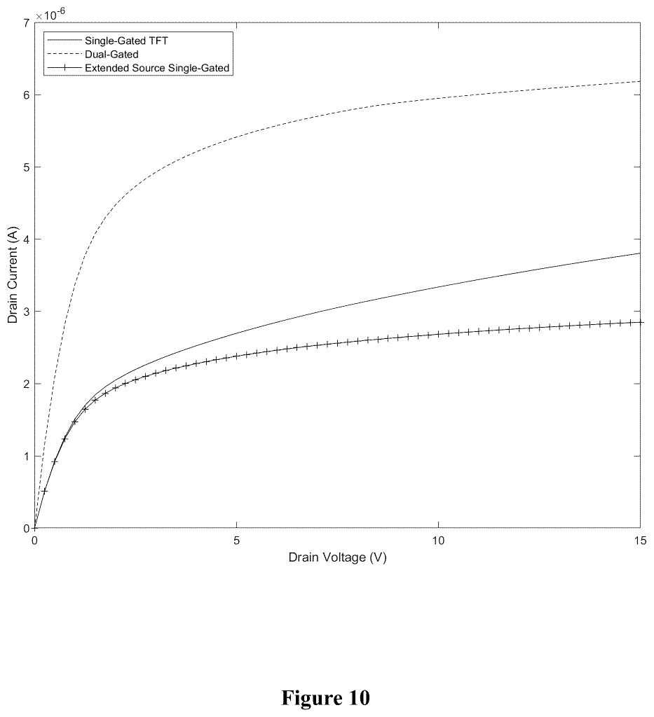

FIG. 10 is a graph of drain voltage vs. drain current (output characteristic) of the different TFT architectures, simulated using TCAD. As illustrated, dual gated TFTs and single gated with extended source result in better saturation performance, i.e., the slope of the current-voltage characteristics is lower. Compared to a single gate TFT with no extended source, the extended source single gate TFT and the dual gated TFT provide a flatter voltage to current relationship, which is the evidence of better saturation performance. Pixel circuits consisting of TFTs with better saturation performance provide better control of drive currents in the saturation region, and hence result in lower grey emission current errors in displays.

All publications, patents and patent applications mentioned in this specification are indicative of the level of skill of those skilled in the art to which this invention pertains and are herein incorporated by reference. The reference to any prior art in this specification is not, and should not be taken as, an acknowledgement or any form of suggestion that such prior art forms part of the common general knowledge.

The invention being thus described, it will be obvious that the same may be varied in many ways. Such variations are not to be regarded as a departure from the scope of the invention, and all such modifications as would be obvious to one skilled in the art are intended to be included within the scope of the following claims.

1. A vertically stacked pixel circuit comprising:
a substrate;
a capacitor layer above the substrate comprising a capacitor having a first capacitor plate, a second capacitor plate, and a dielectric between the first capacitor plate and the second capacitor plate;
a transistor layer above the capacitor layer comprising at least one driving transistor and at least one switching transistor, the driving transistor and the switching transistor connected to the first capacitor plate;
a data line above the transistor layer connected to the switching transistor; and
an organic light emitting diode (OLED) above the data line, the OLED comprising an anode connected to the first capacitor plate.

2. The pixel circuit of claim 1, wherein the driving transistor is connected to the first capacitor plate through a driving transistor gate and the switching transistor is connected to the first capacitor plate through a drain.

3. The pixel circuit of claim 1, wherein the first capacitor plate is closer to the substrate than the second capacitor plate.

4. The pixel circuit of claim 1, wherein one or more the driving transistor and the at least one switching transistor have an extended source electrode.

5. The pixel circuit of claim 1, wherein the anode further comprises a contact metal pad connecting the first capacitor plate to the anode through an anode via, and wherein the anode via and the contact metal pad comprise the same metal.

6. The pixel circuit of claim 1, wherein the driving transistor and the switching transistor are in a single transistor layer.

7. The pixel circuit of claim 1, comprising multiple transistor layers, and wherein the driving transistor is in a different transistor layer than the switching transistor.

8. The pixel circuit of claim 1, wherein the data line is between the transistor layer and the anode.

9. The pixel circuit of claim 1, wherein the vertically stacked pixel circuit is part of a thin film transistor backplane for a display device.

10. The pixel circuit of claim 1, wherein each driving transistor and switching transistor comprises a transparent amorphous-oxide semiconductor.

11. The pixel circuit of claim 10, wherein the transparent amorphous-oxide semiconductor comprises amorphous-indium-gallium-zinc-oxide (a-IGZO).

12. The pixel circuit of claim 1, wherein each driving transistor and switching transistor comprise a gate electrode comprising Molybdenum.

13. The pixel circuit of claim 1, wherein each driving transistor and switching transistor comprise gate insulator and etch stop layers comprising Aluminum oxide.

14. The pixel circuit of claim 1, wherein each driving transistor and switching transistor comprise a passivation layer comprising Silicon Dioxide.

15. The pixel circuit of claim 1, wherein each of the driving transistor and the switching transistor is a single gate transistor, dual gate transistor, or an extended source single gate transistor.

16. The pixel circuit of claim 1, wherein the transistor layer comprises more than one switching transistor.

17. The pixel circuit of claim 1, wherein the first capacitor plate and the second capacitor plate are coplanar with the substrate.

18. A thin film transistor circuit comprising:
a substrate;
a capacitor layer above the substrate comprising a capacitor comprising a first capacitor plate, a second capacitor plate, and a dielectric between the first capacitor plate and the second capacitor plate;
a transistor layer above the capacitor layer comprising at least one driving transistor and at least one switching transistor, the driving transistor and the at least one switching transistor connected to the first capacitor plate; and
at least one inter layer dielectric layer between the capacitor layer and the transistor layer.

19. The transistor circuit of claim 18, comprising multiple transistor layers, and wherein the driving transistor is in a different transistor layer than the at least one switching transistor.

20. The transistor circuit of claim 18, wherein each of the driving transistor and the at least one switching transistor comprises a transparent amorphous-oxide semiconductor.
